(19) United States
(12) Patent Application Publication
(10) Pub. No.: US 2025/0105052 A1
(43) Pub. Date: Mar. 27, 2025

(54) SUBSTRATE SUPPORT UNIT AND SUBSTRATE TREATING APPARATUS INCLUDING THE SAME

(71) Applicant: SEMES CO., LTD., Cheonan-si (KR)

(72) Inventors: Yong Jun BAE, Chungcheongnam-do (KR); Shant ARAKELYAN, Chungcheongnam-do (KR); Jun Seok PARK, Gyeonggi-do (KR); Asatur KHURSHUDYAN, Chungcheongnam-do (KR); Ja Myung GU, Chungcheongnam-do (KR)

(73) Assignee: SEMES CO., LTD., Cheonan-si (KR)

(21) Appl. No.: 18/829,452

(22) Filed: Sep. 10, 2024

(30) Foreign Application Priority Data
Sep. 21, 2023 (KR) 10-2023-0126313

(51) Int. Cl. H01L 21/687; H01J 37/32

(52) U.S. Cl. CPC H01L 21/68785; H01J 37/3244; H01J 37/32724; H01J 2237/002; H01J 2237/334

(57) ABSTRACT

A substrate support unit including a Q-pad capable of minimizing fastening pressure variations that may be caused by heat and a substrate treating apparatus including the substrate support unit are provided. The substrate treating apparatus includes: a chamber housing; a substrate support unit supporting a substrate within the chamber housing; a showerhead unit providing a process gas into the chamber housing; and a plasma generation unit generating plasma for treating the substrate within the chamber housing using the process gas, wherein the substrate support unit includes a base plate, a dielectric layer, which is disposed on the base plate, and a thermal transfer pad, which is disposed between the base plate and the dielectric layer and bonds the base plate and the dielectric layer together, and the thermal transfer pad includes a plurality of corrugated patterns.

### CROSS-REFERENCE TO RELATED APPLICATION

This application claims priority from Korean Patent Application No. 10-2023-0126313 filed on Sep. 21, 2023 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a substrate support unit applicable to equipment treating substrates using plasma, and a substrate treating apparatus including the substrate support unit.

### 2. Description of the Related Art

A Q-pad is a film-type thermal interface material (TIM) used to improve a heat transfer phenomena between two rigid structures. However, when heat is generated through a plasma process, the fastening pressure between the two structures and the Q-pad changes due to a thermal expansion-induced warping. In this case, the pressure applied to the Q-pad may not be sufficient or uniform, which may lead to a significant decrease in the heat transfer capability of the Q-pad.

### SUMMARY

Aspects of the present disclosure provide a substrate support unit including a Q-pad capable of minimizing fastening pressure variations that may be caused by heat and a substrate treating apparatus including the substrate support unit.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a substrate treating apparatus includes: a chamber housing; a substrate support unit supporting a substrate within the chamber housing; a showerhead unit providing a process gas into the chamber housing; and a plasma generation unit generating plasma for treating the substrate within the chamber housing using the process gas, wherein the substrate support unit includes a base plate, a dielectric layer, which is disposed on the base plate, and a thermal transfer pad, which is disposed between the base plate and the dielectric layer and bonds the base plate and the dielectric layer together, and the thermal transfer pad includes a plurality of corrugated patterns.

According to another aspect of the present disclosure, a substrate treating apparatus supports a substrate in equipment that treats the substrate using plasma, and includes: a base plate; a dielectric layer disposed on the base plate; and a thermal transfer pad disposed between the base plate and the dielectric layer and bonding the base plate and the dielectric layer together, wherein the thermal transfer pad includes a plurality of corrugated patterns.

According to another aspect of the present disclosure, a substrate treating apparatus includes: a chamber housing; a substrate support unit supporting a substrate within the chamber housing; a showerhead unit providing a process gas into the chamber housing; and a plasma generation unit generating plasma for treating the substrate within the chamber housing using the process gas, wherein the substrate support unit includes a base plate, a dielectric layer, which is disposed on the base plate, and a thermal transfer pad, which is disposed between the base plate and the dielectric layer and bonds the base plate and the dielectric layer together, the thermal transfer pad includes a film body, a plurality of first protrusion patterns, which are formed on an upper surface of the film body, and a plurality of second protrusion patterns, which are formed on a lower surface of the film body, and the first protrusion patterns and the second protrusion patterns are symmetrically formed in a vertical direction and are formed of the same material

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a first exemplary cross-sectional view illustrating the internal configuration of a substrate treating apparatus;

FIG. 2 is a second exemplary cross-sectional view illustrating the internal configuration of the substrate treating apparatus;

FIG. 3 is a third exemplary cross-sectional view illustrating the internal configuration of the substrate treating apparatus;

FIG. 4 is a first exemplary schematic view illustrating a substrate support unit including a thermal transfer pad;

FIG. 5 is a first exemplary schematic view illustrating the structure of the thermal transfer pad;

FIG. 6 is a second exemplary schematic view illustrating the structure of the thermal transfer pad;

FIG. 7 is a third exemplary schematic view illustrating the structure of the thermal transfer pad;

FIG. 8 is a fourth exemplary schematic view illustrating the structure of the thermal transfer pad;

FIG. 9 is a fifth exemplary schematic view illustrating the structure of the thermal transfer pad;

FIG. 10 is a sixth exemplary schematic view illustrating the structure of the thermal transfer pad;

FIG. 11 is a first exemplary schematic view illustrating how to fabricate the heat transfer pad;

FIG. 12 is a second exemplary schematic view how to fabricate the thermal transfer pad;

FIG. 13 is a third exemplary schematic view illustrating how to fabricate the thermal transfer pad;

FIG. 14 is a first exemplary schematic view illustrating the structure of a thermal transfer pad including a coating layer;

FIG. 15 is a second exemplary schematic view illustrating the structure of the thermal transfer pad including a coating layer;

FIG. 16 is a third exemplary schematic view illustrating the structure of the thermal transfer pad including a coating layer;

FIG. 17 is a graph showing experimental results for the thermal transfer performance of a thermal transfer pad according to an embodiment of the present disclosure; and

FIG. 18 is a second exemplary schematic view illustrating the substrate support unit including a thermal transfer pad.

### DETAILED DESCRIPTION

Embodiments of the present disclosure will hereinafter be described with reference to the accompanying drawings. The same reference numerals are used for identical components in the drawings, and redundant explanations for these components are omitted.

In the present disclosure, a Q-pad can maintain a high fastening pressure even when thermal expansion occurs due to a plasma process. The Q-pad can be provided in a substrate support unit that supports a substrate within a substrate treating apparatus. The substrate treating apparatus will hereinafter be described first, followed by an explanation of the Q-pad provided in the substrate support unit.

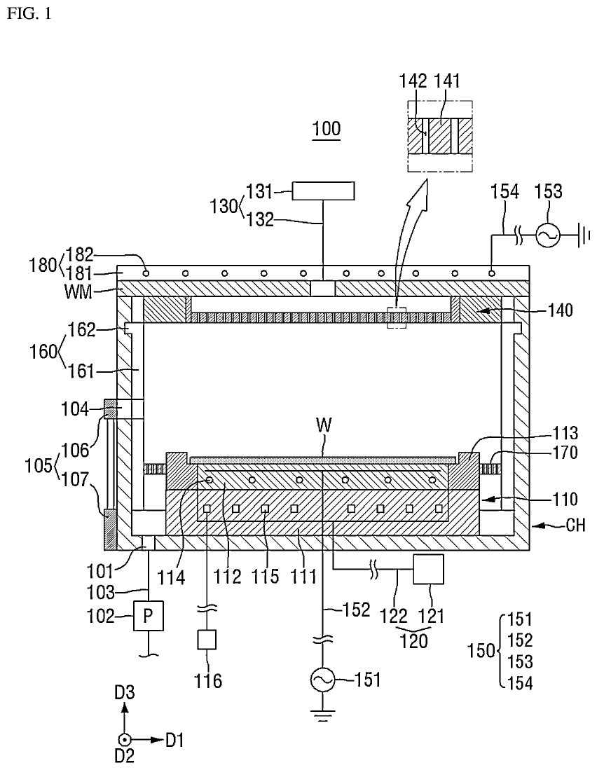

FIG. 1 is a first exemplary cross-sectional view illustrating the internal configuration of the substrate treating apparatus. Referring to FIG. 1, a substrate treating apparatus 100 may be configured to include a chamber housing CH, a substrate support unit 110, a cleaning gas supply unit 120, a process gas supply unit 130, a showerhead unit 140, a plasma generation unit 150, a liner unit 160, a baffle unit 170, a window module WM, and an antenna unit 180.

First and second directions D1 and D2, which are horizontal directions, form a plane. For example, the first direction D1 may be a front-to-back direction, and the second direction D2 may be a left-to-right direction. Alternatively, the first direction D1 may be the left-to-right direction, and the second direction D2 may be the front-to-back direction. A third direction D3, which is a vertical direction, is perpendicular to the plane formed by the first and second directions D1 and D2. The third direction D3 may be a top-to-bottom direction.

The substrate treating apparatus 100 may treat a substrate W using plasma. The substrate treating apparatus 100 may treat the substrate W using a dry method. The substrate treating apparatus 100 may treat the substrate W in, for example, a vacuum environment. The substrate treating apparatus 100 may treat the substrate W using an etching process. However, the present disclosure is not limited to this. Alternatively, the substrate treating apparatus 100 may treat the substrate W using a deposition or cleaning process.

The chamber housing CH provides a space where a process of treating the substrate W using plasma, i.e., a plasma process, takes place. The chamber housing CH may be formed of alumite with an anodic oxide film, and the inside of the chamber housing CH may be configured to be hermetically sealed. The chamber housing CH may be provided in a cylindrical shape, but the present disclosure is not limited thereto. That is, the chamber housing CH may be provided in various other shapes. The chamber housing CH may be equipped with an exhaust hole 101 at its lower part.

The exhaust hole 101 may be connected to an exhaust line 103, which is equipped with a pump 102. The exhaust hole 101 may discharge reaction byproducts generated during the plasma process and residual gases within the chamber housing CH to the outside of the chamber housing CH via the exhaust line 103. In this case, the internal space of the chamber housing CH may be depressurized.

An opening 104 may be formed by penetrating a sidewall of the chamber housing CH. The opening 104 may be provided as a passage for the substrate W to enter and exit the interior of the chamber housing CH. For example, the opening 104 may be configured to be opened and closed automatically by a door assembly 105.

The door assembly 105 may be configured to include an outer door 106 and a door actuator 107. The outer door 106 may open and close the opening 104 from an outer wall of the chamber housing CH. The outer door 106 may be movable in the height direction of the substrate treating apparatus 100, i.e., the third direction D3, under the control of the door actuator 107. The door actuator 107 may operate using at least one element selected from among a motor, a hydraulic cylinder, and a pneumatic cylinder.

The substrate support unit 110 is installed in a lower area within the chamber housing CH. The substrate support unit 110 may use an electrostatic force to attract and support the substrate W, but the present disclosure is not limited thereto. For example, the substrate support unit 110 may be provided as an electrostatic chuck (ESC), but the present disclosure is not limited thereto. Alternatively, the substrate support unit 110 may use various other methods such as vacuum, mechanical clamping, etc., to support the substrate W.

When the substrate support unit 110 is provided as an ESC, the substrate support unit 110 may be configured to include a base plate 111 and a dielectric layer 212. The dielectric layer 112 is disposed on the base plate 111 and may adsorb and support the substrate W mounted thereon. The base plate 111 may be provided as, for example, an aluminum body. The dielectric layer 112 may be formed of, for example, a ceramic material.

A ring structure 113 is provided to surround an outer edge region of the dielectric layer 112. In a case where a plasma process occurs within the chamber housing CH, the ring structure 113 may serve to focus ions onto the substrate W. The ring structure 113 may be formed of a silicon material. For example, the ring structure 113 may be provided as a focus ring.

Although not illustrated in FIG. 1, the ring structure 113 may further include an edge ring. The edge ring may be provided to surround the outer region of the ring structure 113. The edge ring may prevent the sides of the dielectric layer 112 from being damaged by plasma. The edge ring may be formed of, for example, an insulating material, such as quartz.

Heating elements 114 and cooling elements 115 are provided to maintain the substrate W at a processing temperature when a substrate treatment process is performed within the chamber housing CH. The heating elements 114 may be provided as heating wires to raise the temperature of the substrate W. For example, the heating elements 114 may be installed within the dielectric layer 112. The heating elements 114 may not be provided within the substrate support unit 110. The cooling elements 115 may be provided as cooling lines through which a refrigerant flows to lower the temperature of the substrate W. For example, the cooling elements 115 may be installed within the base plate 111. A chiller 116 may supply the refrigerant to the cooling elements 115. The chiller 116 may use cooling water as the refrigerant, but the present disclosure is not limited thereto. Alternatively, the chiller 116 may further use a helium (He) gas as the refrigerant. Yet alternatively, the chiller 116 may use only one of cooling water and a He gas as the refrigerant.

The cleaning gas supply unit 120 provides a cleaning gas to the dielectric layer 112 or the ring structure 113 to remove any residual foreign material on the dielectric layer 112 or the ring structure 113. For example, the cleaning gas supply unit 120 may provide a nitrogen (N₂) gas as the cleaning gas.

The cleaning gas supply unit 120 may include a cleaning gas supply source 121 and a cleaning gas supply line 122. The cleaning gas supply line 122 may be connected to the space between the dielectric layer 112 and the ring structure 113. The cleaning gas supplied by the cleaning gas supply source 121 may move through the cleaning gas supply line 122 into the space between the dielectric layer 112 and the ring structure 113 to remove any foreign material that remains on the edge of the dielectric layer 112 or the top of the ring structure 113.

The process gas supply unit 130 provides a process gas into the chamber housing CH. The process gas supply unit 130 may provide the process gas through a hole formed to penetrate a top cover of the chamber housing CH, i.e., a window module WM, but the present disclosure is not limited thereto. Alternatively, the process gas supply unit 130 may provide the process gas through a hole formed to penetrate a sidewall of the chamber housing CH.

The process gas supply unit 130 may include a process gas supply source 131 and a process gas supply line 132. The process gas supply source 131 may provide a gas used for treating the semiconductor substrate W as the process gas. A single process gas supply source 131 may be provided within the substrate treating apparatus 100, but the present disclosure is not limited thereto. Alternatively, a plurality of process gas supply sources 131 may be provided within the substrate treating apparatus 100. In this case, the plurality of process gas supply sources 131 may provide the same type of process gas or different types of process gases.

The showerhead unit 140 sprays the process gas provided from the process gas supply source 131 over the entire area on the semiconductor substrate W located in the internal space of the chamber housing CH. The showerhead unit 140 may be connected to the process gas supply source 131 through the process gas supply line 132.

The showerhead unit 140 is disposed in the internal space of the chamber housing CH and may include a unit body 141 and a plurality of gas feeding holes 142. The gas feeding holes 142 may be formed to penetrate the surface of the unit body 141 in the third direction D3. The gas feeding holes 142 may be spaced apart from one another at regular intervals on the surface of the unit body 141. The showerhead unit 140 may uniformly spray the process gas through the gas feeding holes 142 over the entire area of the semiconductor substrate W.

The showerhead unit 140 may be installed in the chamber housing CH to face the substrate support unit 110 in the third direction D3. The showerhead unit 140 may be provided with a larger diameter than the dielectric layer 112, but the present disclosure is not limited thereto. Alternatively, the showerhead unit 140 may be provided with the same diameter as the dielectric layer 112. The showerhead unit 140 may be formed of silicon as the material, but the present disclosure is not limited thereto. Alternatively, the showerhead unit 140 may be formed of a metal.

Although not illustrated in FIG. 1, the showerhead unit 140 may be divided into a plurality of head modules. For example, the showerhead unit 140 may be divided into three head modules, i.e., first, second, and third head modules. The first head module may be disposed at a position corresponding to a central zone of the semiconductor substrate W. The second head module may be disposed to surround the outer edge of the first head module. The second head module may be disposed at a position corresponding to a middle zone of the semiconductor substrate W. The third head module may be disposed to surround the outer edge of the second head module. The third head module may be disposed at a position corresponding to an edge zone of the semiconductor substrate W.

The plasma generation unit 150 generates plasma from the gas remaining in a discharge space. Here, the discharge space may be the internal space of the chamber housing CH and may be formed between the showerhead unit 140 and the window module WM. Alternatively, the discharge space may be formed between the substrate support unit 110 and the showerhead unit 140. If the discharge space is formed between the substrate support unit 110 and the showerhead unit 140, the discharge space may be divided into the plasma region and the process region. The plasma region may be formed above the process region.

The plasma generation unit 150 may generate plasma in the discharge space using an inductively coupled plasma (ICP) source. For example, the plasma generation unit 150 may generate plasma in the discharge space using the dielectric layer 112 and the antenna unit 180 as a first electrode (or a lower electrode) and a second electrode (or an upper electrode), respectively.

However, the present disclosure is not limited to this. Alternatively, the plasma generation unit 150 may use a capacitively coupled plasma (CCP) source to generate plasma in the discharge space. For example, the plasma generation unit 150 may generate plasma in the discharge space using the dielectric layer 112 and the showerhead unit 140 as a first electrode (or a lower electrode) and a second electrode (or an upper electrode), respectively. A case where the plasma generation unit 150 uses a CCP source will be described later in further detail.

The plasma generation unit 150 may be configured to include a first high-frequency power source 151, a first transmission line 152, a second high-frequency power source 153, and a second transmission line 154.

The first high-frequency power source 151 applies radio frequency (RF) power to the first electrode. The first high-frequency power source 151 may serve as a plasma source to generate plasma within the chamber housing CH. However, the present disclosure is not limited to this. The first and second high-frequency power sources 151 and 153 may also control the characteristics of plasma within the chamber housing CH.

A plurality of first high-frequency power sources 151 may be provided within the substrate treating apparatus 100. In this case, the plasma generation unit 150 may include a first matching network, which is electrically connected to each of the plurality of first high-frequency power sources 151. If frequency powers with different magnitudes are input from the plurality of first high-frequency power sources 151, the first matching network may match and apply the frequency powers to the first electrode.

The first transmission line 152 may connect the first electrode and a ground source. The first high-frequency power source 151 may be installed on the first transmission line 152, but the present disclosure is not limited thereto. The first transmission line 152 may also connect the first electrode and the first high-frequency power source 151. The first transmission line 152 may be provided as, for example, an RF rod.

The second high-frequency power source 153 applies RF power to the second electrode. The second high-frequency power source 153 may control the plasma characteristics within the chamber housing CH. For example, the second high-frequency power source 153 may adjust the ion bombardment energy within the chamber housing CH.

A plurality of second high-frequency power sources 153 may be provided within the substrate treating apparatus 100. In this case, the plasma generation unit 150 may include a second matching network, which is electrically connected to each of the plurality of second high-frequency power sources 153. If frequency powers with different magnitudes are input from the plurality of second high-frequency power sources 153, the second matching network may match and apply the frequency powers to the second electrode.

The second transmission line 154 connects the first electrode and the ground source. The second high-frequency power source 153 may be installed on the second transmission line 154.

The liner unit 160, also referred to as a wall liner, protects the interior of the chamber housing CH from arc discharges generated during the excitation of the process gas or from impurities produced during the treatment of the semiconductor substrate W. The liner unit 160 may be formed to cover the inner walls of the chamber housing CH.

The liner unit 160 may include a body 161 and a support ring 162 on the body 161. The support ring 162 may protrude in an outward direction (i.e., the first direction D1) from an upper part of the body 161 and may secure the body of the liner unit 160 to the chamber housing CH.

The baffle unit 170 serves to exhaust byproducts or unreacted gases from a plasma process within the chamber housing CH. The baffle unit 170 may be installed in the space between the substrate support unit 110 and an inner wall of the chamber housing CH (or the liner unit 160), and may be positioned near the exhaust hole 101. The baffle unit 170 may be provided in the shape of a circular ring between the inner wall of the chamber housing CH and the substrate support unit 110.

The baffle unit 170 may include a plurality of slot holes that penetrate the body of the baffle unit 170 in the third direction D3 to control the flow of the process gas within the chamber housing CH. The baffle unit 170 may be formed of a material with etching resistance to minimize damage or deformation caused by radicals within the internal space of the chamber housing CH where plasma is generated. For example, the baffle unit 170 may be formed to include quartz.

The window module WM serves as an upper cover for the chamber housing CH, sealing the internal space of the chamber housing CH. The window module WM may be provided separately from the chamber housing CH, but the present disclosure is not limited thereto. Alternatively, the window module WM may be integrated as part of the chamber housing CH. When provided separately from the chamber housing CH, the window module WM may cover the open top of the chamber housing CH. When integrated as part of the chamber housing CH, the window module WM may be provided in an integral structure with the chamber housing CH.

The window module WM may be formed as a dielectric window, using an insulating material. For example, the window module WM may be formed of alumina. The window module WM may also include a coating film on its surface to suppress particle formation when a plasma process is performed within the internal space of the chamber housing CH.

The antenna unit 180 generates magnetic and electric fields within the internal space of the chamber housing CH to excite the process gas into plasma. The antenna unit 180 may operate using RF power supplied from the second high-frequency power source 153. The antenna unit 180 may be provided on the chamber housing CH. For example, the antenna unit 180 may be provided on the window module WM, but the present disclosure is not limited thereto. Alternatively, the antenna unit 180 may be provided on a sidewall of the chamber housing CH.

The antenna unit 180 may include a body 181 and an antenna 182 either within the body 181 or on the surface of the body 181. The antenna 182 may be provided to form a closed loop using a coil. The antenna 182 may be formed in various shapes, such as a spiral shape, along the width direction of the chamber housing CH, i.e., the first direction D1.

The antenna unit 180 may be formed to have a planar structure, but the present disclosure is not limited thereto. Alternatively, the antenna unit 180 may be formed to have a cylindrical structure. When formed in a planar structure, the antenna unit 180 may be provided on the chamber housing CH. When formed in a cylindrical structure, the antenna unit 180 may be provided to surround the outer walls of the chamber housing CH.

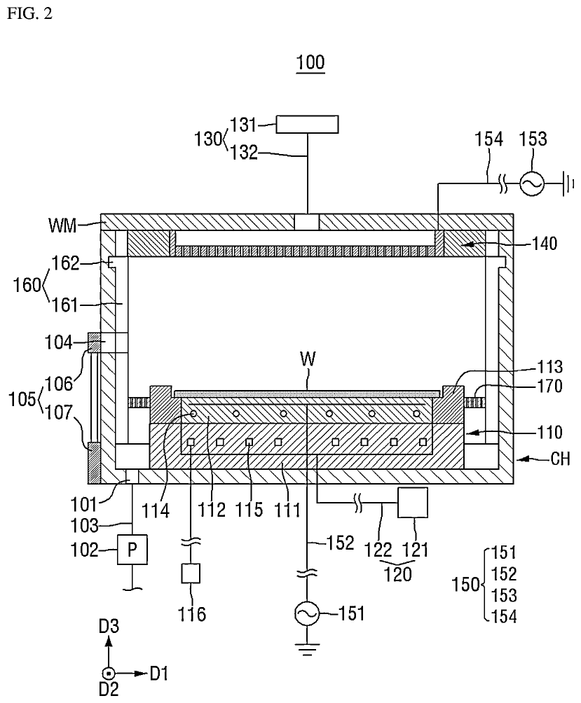

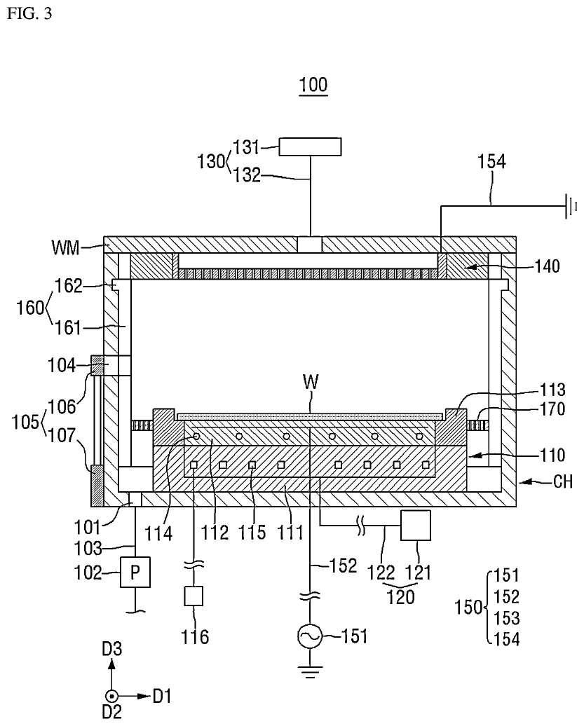

A case where the plasma generation unit 150 uses an ICP source to generate plasma in the discharge space has been described so far with reference to FIG. 1. A case where the plasma generation unit 150 uses a CCP source to generate plasma in the discharge space will hereinafter be described with reference to FIGS. 2 and 3, focusing mainly on the differences with the embodiment of FIG. 1.

FIG. 2 is a second exemplary cross-sectional view illustrating the internal configuration of the substrate treating apparatus. FIG. 3 is a third exemplary cross-sectional view illustrating the internal configuration of the substrate treating apparatus.

Referring to FIGS. 2 and 3, the substrate treating apparatus 100 may be configured to include a chamber housing CH, a substrate support unit 110, a cleaning gas supply unit 120, a process gas supply unit 130, a showerhead unit 140, a plasma generation unit 150, a liner unit 160, a baffle unit 170, and a window module WM. In other words, the substrate treating apparatus 100, unlike its counterpart of FIG. 1, may not include an antenna unit 180.

Referring to FIG. 2, the plasma generation unit 150 may be configured to include a first high-frequency power source 151, a first transmission line 152, a second high-frequency power source 153, and a second transmission line 154, but the present disclosure is not limited thereto. Alternatively, referring to FIG. 3, the plasma generation unit 150 may be configured to include the first high-frequency power source 151, the first transmission line 152, and the second transmission line 154. That is, the plasma generation unit 150, unlike its counterpart of FIG. 2, may not include a second high-frequency power source 153.

Referring to the example of FIG. 1, the second transmission line 154 may be connected to the antenna 182 of the antenna unit 180, and the second high-frequency power source 153 may apply RF power to the antenna 182 of the antenna unit 180. On the contrary, referring to the example of FIG. 2, the second transmission line 154 may be connected to a body 141 of the showerhead unit 140, and the second high-frequency power source 153 may apply RF power to the body 141 of the showerhead unit 140.

In the example of FIG. 2, the second high-frequency power source 153 may be installed on the second transmission line 154. In the example of FIG. 3, the second high-frequency power source 153 may not be installed on the second transmission line 154. If the second high-frequency power source 153 is installed on the second transmission line 154, the plasma generation unit 150 may apply multiple frequencies to the substrate treating apparatus 100.

Although not specifically illustrated in FIGS. 1 through 3, the substrate treating apparatus 100 may further include a control device. The control device controls the overall operation of each component of the substrate treating apparatus 100. For example, the control device may control an overall substrate treating process.

The control device may include a processor that executes control for each component of the substrate treating apparatus 100, a network that communicates with each component of the substrate treating apparatus 100 in a wired or wireless manner, and storage means for storing one or more instructions related to functions or operations for controlling each component of the substrate treating apparatus 100, processing (or treatment) recipes including instructions, and various data. In addition, the control device may further include a user interface, and the user interface includes input means for operators to perform command input operations to manage the semiconductor manufacturing equipment 100 and output means to visualize and display the operating status of the substrate treating apparatus 100. The control device may be configured as a computing device for data processing and analysis, and command delivery.

Instructions may be provided in the form of computer programs or applications. A computer program may be stored on a computer-readable recording medium and may include one or more instructions. Instructions may include code generated by a compiler, code that can be executed by an interpreter, etc. The storage means may be provided as one or more storage media selected from among a flash memory, a hard-disk drive (HDD), a solid-state drive (SSD), a card-type memory, a random-access memory (RAM), a static RAM (SRAM), a read-only memory (ROM), an electrically erasable programmable ROM (EEPROM), a programmable ROM (PROM), a magnetic memory, a magnetic disk, and an optical disk.

As previously described, the Q-pad can be applied to the substrate treating apparatus 100 that uses plasma, and can be used to improve a heat transfer phenomena between two different structures. The Q-pad will hereinafter be defined and described as a thermal transfer pad.

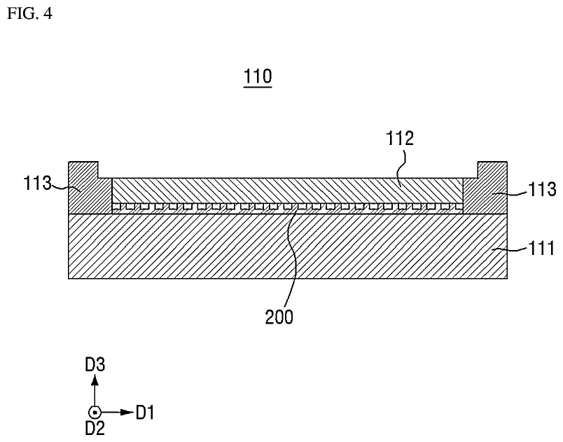

FIG. 4 is a first exemplary diagram illustrating the structure of a substrate support unit including a thermal transfer pad. Referring to FIG. 4, a thermal transfer pad 200 may be provided between the base plate 111 and the dielectric layer 112. The thermal transfer pad 200 may serve to bond the base plate 111 and the dielectric layer 112 together. The thermal transfer pad 200 may be provided as a bonding layer.

The thermal transfer pad 200 may be formed of a material such as aluminum, polyimide, or graphite. The thermal transfer pad 200 may be partially or fully coated with a material such as a polymer or graphite. When a coating layer is formed on the surface of the thermal transfer pad 200, the thermal transfer pad 200 can prevent damage caused by plasma and can improve the adhesion between the base plate 111 and the dielectric layer 112.

The heat transfer capability of the thermal transfer pad 200 may vary depending on the pressure applied to its contact surface. Therefore, to increase the heat transfer capability of the thermal transfer pad 200, sufficient pressure needs to be applied when assembling two structures, i.e., the base plate 111 and the dielectric layer 112. However, even if sufficient pressure is applied initially at room temperature, the two structures may warp later due to thermal deformation caused by the occurrence of a high temperature within the chamber housing CH during a plasma process, and the fastening pressure between the thermal transfer pad 200 and the two structures may change.

The thermal transfer pad 200 may be formed as a flat plate. When the thermal transfer pad 200 is formed as a flat plate, the area of the thermal transfer pad 200 that is subjected to a force may widen, allowing for the pressure to be dispersed and making it easier for structural deformation to occur. When a flat plate-type thermal transfer pad 200 is applied to the substrate treating apparatus 100, the fastening pressure of the thermal transfer pad 200 may continuously decrease due to thermal deformation, and the heat transfer capability of the thermal transfer pad 200 may also considerably decrease.

The thermal transfer pad 200 may be formed with a plurality of corrugated patterns. When the thermal transfer pad 200 is formed with the corrugated patterns, sufficient contact pressure can be secured even if structural deformation occurs, and as a result, the reduction of thermal transfer capability can be prevented.

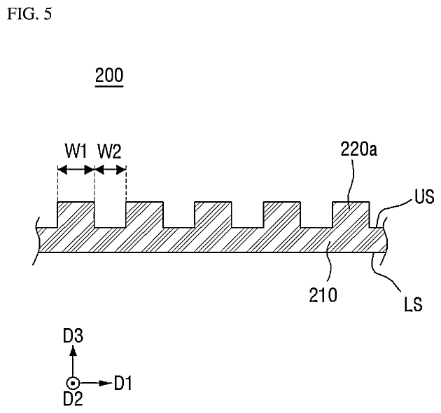

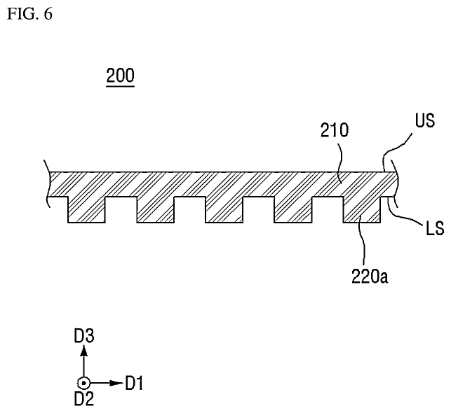

The thermal transfer pad 200 may be provided as a film sheet. Referring to FIG. 5, the thermal transfer pad 200 may include a film body 210 and a plurality of first protrusion patterns 220a on an upper surface US of the film body 210, but the present disclosure is not limited thereto. Alternatively, referring to FIG. 6, the thermal transfer pad 200 may include a plurality of first protrusion patterns 220a on a lower surface LS of the film body 210.

The first protrusion patterns 220a may be formed to have the same width. For example, the first protrusion patterns 220a may be formed to have a width W1. The first protrusion patterns 220a may be spaced apart from one another at regular intervals. For example, the first protrusion patterns 220a may be spaced apart from one another at intervals of a distance W2. The width W1 may be the same as the distance W2 (i.e., W=W2), but the present disclosure is not limited thereto. Alternatively, the width W1 may be greater than the distance W2 (i.e., W1>W2). Yet alternatively, the width W1 may be smaller than the distance W2 (i.e., W1<W2). To expand the contact area between the thermal transfer pad 200 and the dielectric layer 112, the width W1 may be set to be equal to or greater than the distance W2 (i.e., W1≥W2). FIG. 5 is a first exemplary schematic view illustrating the structure of the thermal transfer pad. FIG. 6 is a second exemplary schematic view illustrating the structure of the thermal transfer pad.

The thermal transfer pad 200 may partially include the corrugated patterns. For example, the thermal transfer pad 200 may include the corrugated patterns across the entire upper surface US, but not across the entire lower surface LS. Alternatively, the thermal transfer pad 200 may include the corrugated patterns only on a portion of the upper surface US, but not across the entire lower surface LS. Yet alternatively, the thermal transfer pad 200 may not include the corrugated patterns across the entire upper surface US, but may include the corrugated patterns on a portion of the lower surface LS. Still alternatively, the thermal transfer pad 200 may not include the corrugated patterns across the entire upper surface US, but may include the corrugated patterns across the entire lower surface LS.

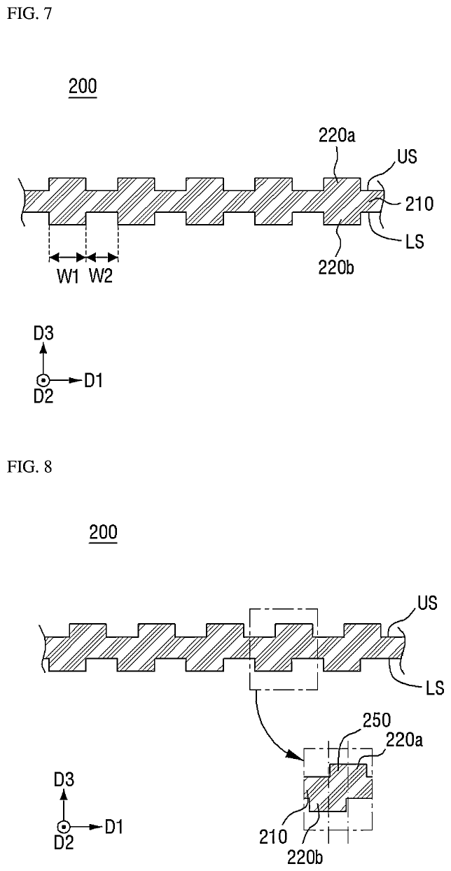

The thermal transfer pad 200 may include the corrugation pattern on only one of the upper and lower surfaces US and LS, but the present disclosure is not limited thereto. Alternatively, the thermal transfer pad 200 may include the corrugation pattern on both the upper and lower surfaces US and LS. Referring to FIG. 7, the thermal transfer pad 200 may include a plurality of first protrusion patterns 220a on the upper surface US and a plurality of second protrusion patterns 220b on the lower surface LS. The first protrusion patterns 220a may be formed across the entire upper surface US, but the present disclosure is not limited thereto. Alternatively, the first protrusion patterns 220a may be formed only on a portion of the upper surface US. Similarly, the second protrusion patterns 220b may be formed across the entire lower surface LS, but the present disclosure is not limited thereto. Alternatively, the second protrusion patterns 220b may be formed only on a portion of the lower surface LS.

The first protrusion patterns 220a and the second protrusion patterns 220b may be symmetrically formed in the third direction D3. When the first protrusion patterns 220a and the second protrusion patterns 220b are symmetrically formed in the third direction D3 being symmetrically formed in the third direction D3, it means that if the film body 210 is folded, the first protrusion patterns 220a and the second protrusion patterns 220b may completely overlap. However, the present disclosure is not limited to this. Alternatively, the first protrusion patterns 220a and the second protrusion patterns 220b may be asymmetrically formed in the third direction D3. FIG. 7 is a third exemplary schematic view illustrating the structure of the thermal transfer pad.

Referring to FIG. 8, when the first protrusion patterns 220a and the second protrusion patterns 220b are asymmetrically formed in the third direction D3, the first protrusion patterns 220a and the second protrusion patterns 220b may partially overlap in the third direction D3. That is, if the film body 210 is folded, the first protrusion patterns 220a and the second protrusion patterns 220b may partially overlap. Each overlapping area 250 may include portions of both first and second protrusion patterns 220a and 220b that overlap with each other. FIG. 8 is a fourth exemplary schematic view illustrating the structure of the thermal transfer pad.

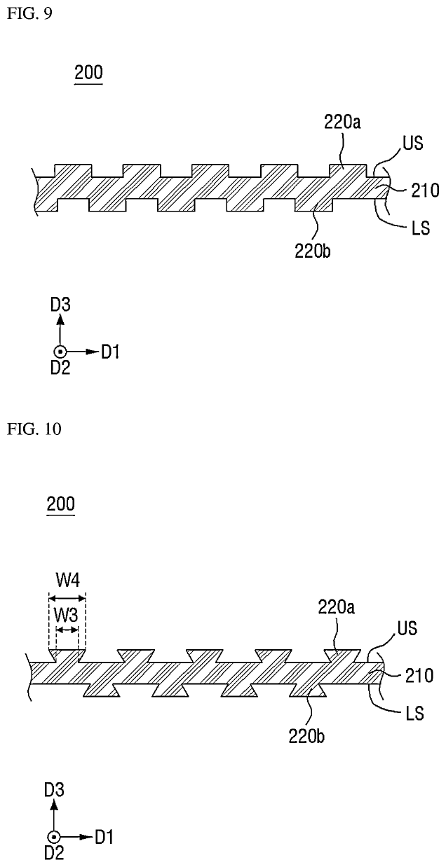

However, the present disclosure is not limited to this. Alternatively, referring to FIG. 9, the first protrusion patterns 220a and the second protrusion patterns 220b do not overlap entirely in the third direction D3. That is, if the film body 210 is folded, the first protrusion patterns 220a and the second protrusion patterns 220b may not overlap entirely. FIG. 9 is a fifth exemplary schematic view illustrating the structure of the thermal transfer pad.

The second protrusion patterns 220b may be formed to have the same width. The second protrusion patterns 220b may be formed to have the same width as the first protrusion patterns 220a. For example, the second protrusion patterns 220b may be formed to have the width W1, but the present disclosure is not limited thereto. Alternatively, the second protrusion patterns 220b may be formed to have a different width from the first protrusion patterns 220a.

The second protrusion patterns 220b may be spaced apart from one another at regular intervals. The second protrusion patterns 220b may be spaced apart from one another at intervals of the same distance at the first protrusion patterns 220a. For example, the second protrusion patterns 220b may be spaced apart from one another at intervals of the distance W2, but the present disclosure is not limited thereto. Alternatively, the second protrusion patterns 220b may be spaced apart at intervals of a different distance from the first protrusion patterns 220a.

The first protrusion patterns 220a may be formed to have the same width on both their outer and inner sides, but the present disclosure is not limited thereto. Alternatively, the first protrusion patterns 220a may be formed to have different widths on their outer and inner sides. Referring to FIG. 10, the first protrusion patterns 220a may be formed to have a greater width on their outer side than on their inner side. The width of the first protrusion patterns 220a on the outer sides of the first protrusion patterns 220a is W4 and the width of the first protrusion patterns 220a on the inner sides of the first protrusion patterns 220a is W3, the width W4 may be greater than the width W3 (i.e., W4>W3). Conversely, the first protrusion patterns 220a may also be formed to have a smaller width on their outer sides than on their inner sides.

The first protrusion patterns 220a may have a rectangular cross-sectional view along the third direction D3, but the present disclosure is not limited thereto. That is, the first protrusion patterns 220a may have various other cross-sectional shapes. For example, if the first protrusion patterns 220a have a triangular or circular cross-sectional shape, the first protrusion patterns 220a may be formed to have a smaller width on their outer sides than on their inner sides. However, if the first protrusion patterns 220a have a smaller width on their outer sides than on their inner sides, it may be inefficient for heat transfer. Therefore, preferably, the first protrusion patterns 220a may be formed to have the same width on their outer and inner sides, or have a greater width on their outer sides than on their inner sides (i.e., W4≥W3).

The first protrusion patterns 220a may be formed to gradually widen in the third direction D3, as illustrated in FIG. 10, or may be formed to have a uniform width in the third direction D3, as illustrated in FIG. 7. Similarly, the second protrusion patterns 220b may also be formed to gradually widen in the third direction D3, as illustrated in FIG. 10, or may be formed to have a uniform width in the third direction D3, as illustrated in FIG. 7. Referring to FIGS. 7 and 10, the shape of the second protrusion patterns 220b may be the same as the shape of the first protrusion patterns 220a, but the present disclosure is limited thereto. FIG. 10 is a sixth exemplary schematic view illustrating the structure of the heat transfer pad.

As previously described, the heat transfer pad 200 may be formed to have a plurality of first protrusion patterns 220a on the upper surface US of the film body 210. Alternatively, the heat transfer pad 200 may be formed to have a plurality of first protrusion patterns 220a on the lower surface LS of the film body 210. Yet alternatively, the heat transfer pad 200 may be formed to have a plurality of first protrusion patterns 220a and a plurality of second protrusion patterns 220b on the upper surface US and the lower surface LS, respectively, of the film body 210.

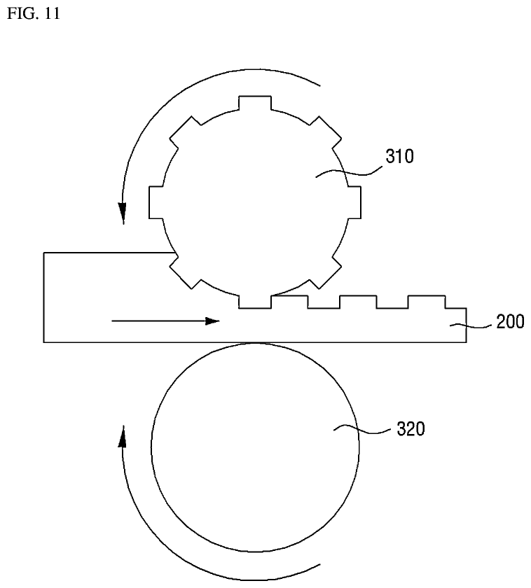

The heat transfer pad 200 may be fabricated using rollers. Referring to FIG. 11, first and second rollers 310 and 320 may be disposed on the top and bottom, respectively, of a film product, and the film product may be passed through between the first and second rollers 310 and 320 while rotating the first and second rollers 310 and 320, thereby obtaining the heat transfer pad 200 with the corrugated patterns.

The first and second rollers 310 and 320 may rotate in opposite directions. For example, the first roller 310 may rotate in a counterclockwise direction, and the second roller 320 may rotate in a clockwise direction. The film product may move in a left-to-right direction.

Referring to FIG. 11, the first roller 310 may be a rotating body with a plurality of protrusions formed on its surface, and the second roller 320 may be a rotating body with no protrusions formed on its surface. In this case, the heat transfer pad 200 with a plurality of first protrusion patterns 220a formed on the upper surface US of the film body 210 may be obtained. FIG. 11 is a first exemplary schematic view illustrating how to fabricate the heat transfer pad.

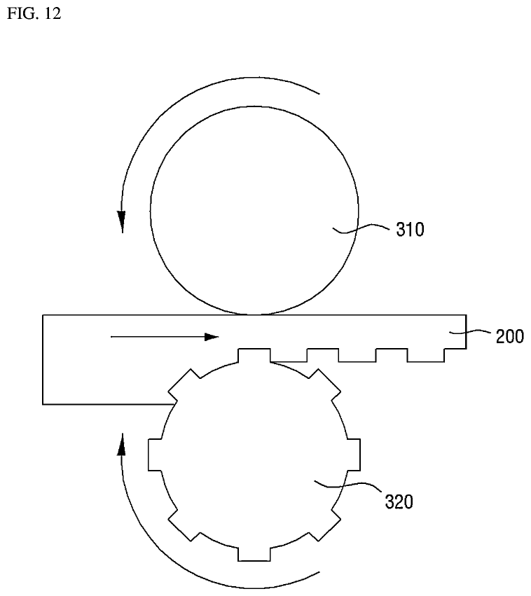

Alternatively, referring to FIG. 12, the first roller 310 may be a rotating body with no protrusions formed on its surface, and the second roller 320 may be a rotating body with a plurality of protrusions formed on its surface. In this case, the heat transfer pad 200 with a plurality of first protrusion patterns 220a formed on the lower surface LS of the film body 210 may be obtained. FIG. 12 is also a second exemplary schematic view illustrating how to fabricate the heat transfer pad.

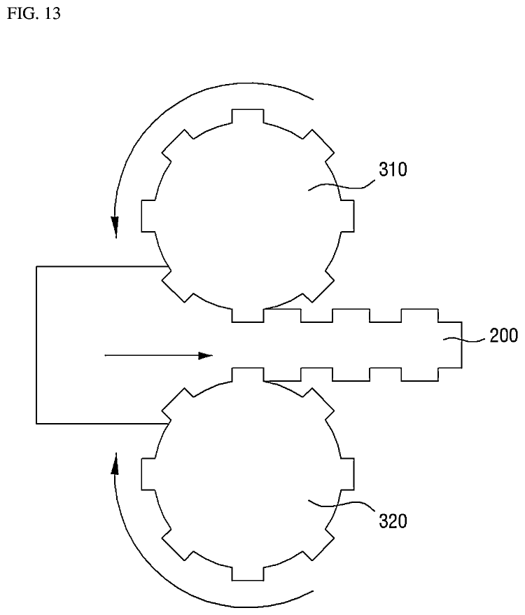

Yet alternatively, referring to FIG. 13, the first roller 310 may be a rotating body with a plurality of protrusions formed on its surface, and the second roller 320 may also be a rotating body with a plurality of protrusions formed on its surface. In this case, the heat transfer pad 200 with a plurality of first protrusion patterns 220a and a plurality of second protrusion patterns 220b formed on the upper surface US and the lower surface LS, respectively, of the film body 210 may be obtained. FIG. 13 is a third exemplary schematic view illustrating how to fabricate the heat transfer pad.

It has been described so far how to fabricate the heat transfer pad 200 with the corrugated patterns using rollers with reference to FIGS. 11 through 13. However, the present disclosure is not limited to the examples of FIGS. 11 through 13, and alternatively, the heat transfer pad 200 with the corrugated patterns may be fabricated through stamping.

The heat transfer pad 200 may consist only of the film body 210, but the present disclosure is not limited thereto. Alternatively, the heat transfer pad 200 may further include a coating layer 230 on the film body 210, and this will hereinafter be described.

The coating layer 230 may be formed on some of the surfaces of the film body 210. For example, the coating layer 230 may be formed on the upper surface US of the film body 210, but the present disclosure is not limited thereto. Alternatively, the coating layer 230 may be formed on all the surfaces of the film body 210. The coating layer 230 may be formed to cover not only the upper surface US but also the lower surface LS of the film body 210.

The coating layer 230 may be formed on the film body 210 using a pattern transfer printing method, but the present disclosure is not limited thereto. Alternatively, the coating layer 230 may be formed on the film body 210 using an electro-spray machine or an electro-spinning machine. The heat transfer pad 200 may be formed of a porous film.

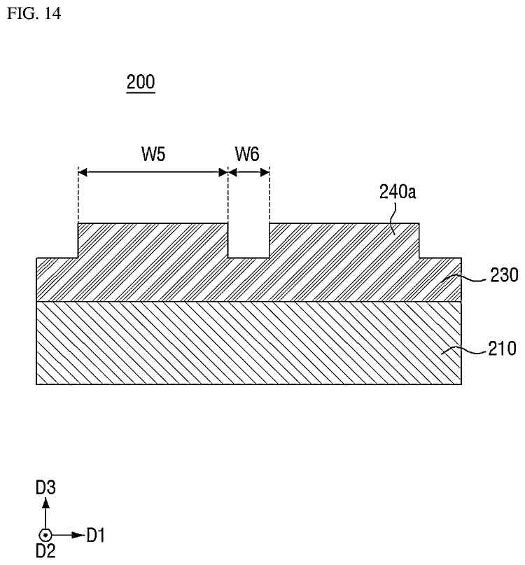

When the heat transfer pad 200 includes the film body 210 and the coating layer 230, the coating layer 230 may include a plurality of corrugated patterns while the film body 210 may not include corrugated patterns. Referring to FIG. 14, the coating layer 230 may include a plurality of third protrusion patterns 240a on its upper surface, and the film body 210 may not include first protrusion patterns 220a and second protrusion patterns 220b on the upper and lower surfaces US and LS, respectively.

The third protrusion patterns 240a may be formed to have the same width. For example, the third protrusion patterns 240a may be formed to have a width W5. The third protrusion patterns 240a may be spaced apart from one another at regular intervals. For example, the third protrusions 240a may be spaced apart from one another at intervals of a distance W6. The width W5 may be greater than the distance W6 (i.e., W5>W6), but the present disclosure is not limited thereto. Alternatively, the width W5 may be equal to the distance W6 (i.e., W5=W6). FIG. 14 is a first exemplary schematic view illustrating the structure of a heat transfer pad including a coating layer.

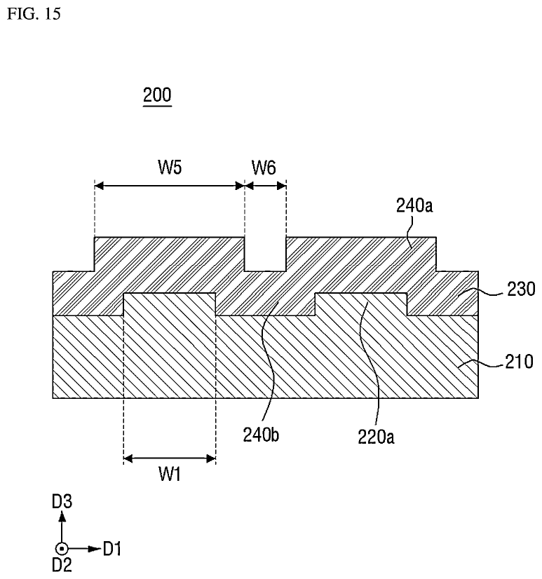

Alternatively, when the heat transfer pad 200 includes the film body 210 and the coating layer 230, the film body 210 and the coating layer 230 may both include corrugated patterns. Referring to FIG. 15, the film body 210 may include a plurality of first protrusion patterns 220a on the upper surface LS. The coating layer 230 may include a plurality of third protrusion patterns 240a and a plurality of fourth protrusion patterns 240b on its upper and lower surfaces, respectively. The fourth protrusion patterns 240b may be formed on the lower surface of the coating layer 230 under the same conditions as the third protrusion patterns 240a. The fourth protrusion patterns 240b may be formed to engage with the first protrusion patterns 220a.

The width of the third protrusion patterns 240a, i.e., the width W5, may be greater than the width of the first protrusion patterns 220a, i.e., W1 (i.e., W5>W1). The coating layer 230 may be formed along the profile of the upper surface US of the film body 210 where the first protrusion patterns 220a are formed. The coating layer 230 may be formed to have a uniform thickness. Accordingly, the third protrusion patterns 240a may be formed to be wider than the first protrusion patterns 220a, but the present disclosure is not limited thereto. Alternatively, the third protrusion patterns 240a may be formed to have the same width as the first protrusion patterns 220a.

Meanwhile, contrary to the lower surface LS of the film body 210 of FIG. 15 not being corrugated, a plurality of second protrusion patterns 220b may be formed on the lower surface LS of the film body 210. FIG. 15 is a second exemplary schematic view illustrating the structure of the heat transfer pad including a coating layer.

When the film body 210 and the coating layer 230 both include corrugated patterns, the film body 210 may include a plurality of first protrusion patterns 220a on the upper surface US, and the coating layer 230 may include a plurality of third protrusion patterns 240a on its upper surface. Alternatively, the film body 210 may include a plurality of second protrusion patterns 220b on the lower surface LS, and the coating layer 230 may include a plurality of third protrusion patterns 240a and a plurality of fourth protrusion patterns 240b on its upper and lower surfaces, respectively. Yet alternatively, the film body 210 may include a plurality of second protrusion patterns 220b on the lower surface LS, and the coating layer 230 may include a plurality of third protrusion patterns 240a on its upper surface.

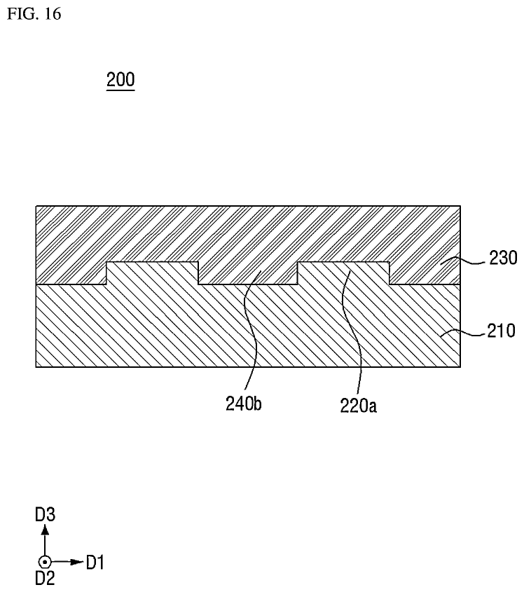

When the film body 210 and the coating layer 230 both include corrugated patterns, the coating layer 230 may include a plurality of third protrusion patterns 240a not on its upper surface but on its lower surface. Referring to FIG. 16, the film body 210 may include a plurality of first protrusion patterns 220a on the upper surface US. The coating layer 230 may include a plurality of third protrusion patterns 240a on its lower surface. The third protrusion patterns 240a may be formed to alternate with the first protrusion patterns 220a. FIG. 16 is a third exemplary schematic view illustrating the structure of the heat transfer pad including a coating layer.

The third protrusion patterns 240a may be formed only on a portion of the upper surface of the coating layer 230, but the is not limited thereto. Alternatively, the third protrusion patterns 240a may be formed on the entire upper surface of the coating layer 230. Similarly, the fourth protrusion patterns 240b may be formed only on a portion of the lower surface of the coating layer 230, but the present disclosure is not limited thereto. Alternatively, the fourth protrusion patterns 240b may be formed on the entire lower surface of the coating layer 230. Additionally, the third protrusion patterns 240a and the fourth protrusion patterns 240b may be symmetrically formed in the third direction D3, but the present disclosure is not limited thereto. Alternatively, the third protrusion patterns 240a and the fourth protrusion patterns 240b may be asymmetrically formed in the third direction D3.

The first protrusion patterns 220a and the second protrusion patterns 220b may be formed on the film body 210 as stripe patterns, but the present disclosure is not limited thereto. Alternatively, the first protrusion patterns 220a and the second protrusion patterns 220b may be formed on the film body 210 as dot patterns. Similarly, the third protrusion patterns 240a and the fourth protrusion patterns 240b may be formed on the coating layer 230 as stripe patterns or dot patterns. Meanwhile, the first protrusion patterns 220a, the second protrusion patterns 220b, the third protrusion patterns 240a, and the fourth protrusion patterns 240b may also be formed using a bump or dome structure.

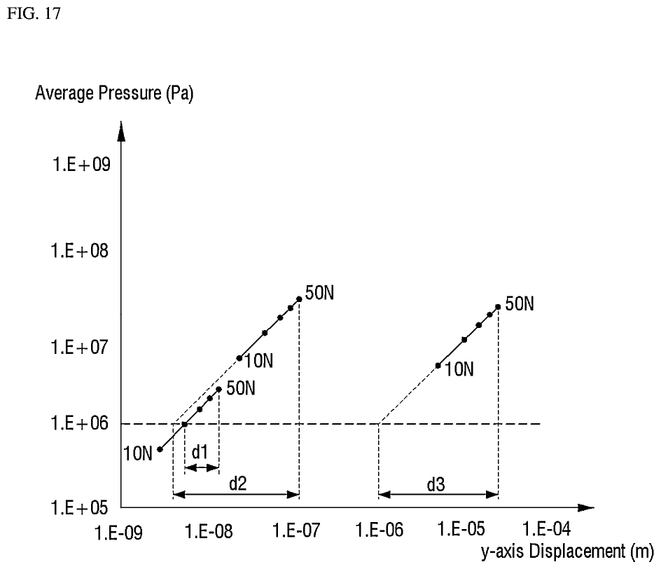

FIG. 17 is a graph showing experimental results for the thermal performance of the heat transfer pad 200. The improved performance of the heat transfer pad 200 due to its surface structure can be confirmed through the results of a simulation, as shown in FIG. 17. In the simulation, structural analyses were conducted for a flat structure (d1), a structure (d2) with protrusions at the same positions on its top and bottom, and a structure (d3) with protrusions at misaligned positions on its top and bottom, and the Q-pads were placed between a structure formed of aluminum (Al) and a structure formed of silicon (Si), and the displacement and pressure when increasing the compressive force from 10 N to 50 N in increments of 10 N are shown in FIG. 17.

The analysis results show that a displacement d needed to reduce the pressure on each of the Q-pads fastened at 50 N to an arbitrary reference pressure of 1.0E+6 Pa or less can be estimated to be greater in the order of d1<d2<d3. Given the displacement d1 (=8.9E−9 m) of the flat structure, “d2” is expected to be tens of times “d1” (i.e., d2/d1˜14.6), and “d3” is expected to be thousands of times “d1” (i.e., d3/d1˜3703). An increase in pressure alone can counteract a decrease in thermal performance that may be caused by deformation, and furthermore, the use of elasticity can counteract a wider range of deformations. This means that the temperature range in which the thermal performance of the Q-pads is maintained can widen. In other words, the first protrusion patterns 220a, the second protrusion patterns 220b, the third protrusion patterns 240a, and the fourth protrusion patterns 240b may be elastic.

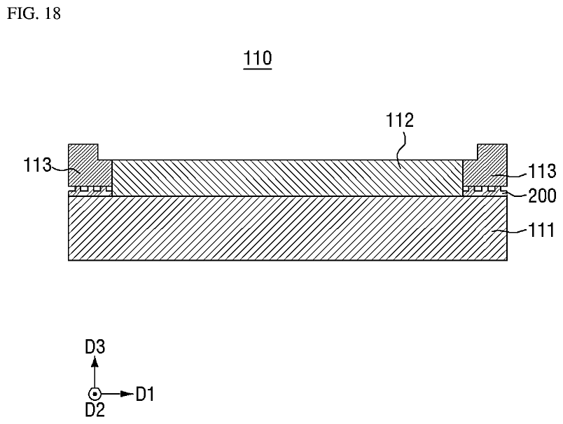

The heat transfer pad 200 has been described so far with reference to FIGS. 1 through 17 as being provided between the base plate 111 and the dielectric layer 112, but the present disclosure is not limited thereto. Alternatively, referring to FIG. 18, the heat transfer pad 200 may be provided between the base plate 111 and the ring structure 113. Yet alternatively, the heat transfer pad 200 may be provided both between the base plate 111 and the dielectric layer 112 and between the base plate 111 and the ring structure 113. FIG. 18 is a second exemplary schematic view illustrating the structure of the substrate support unit including a heat transfer pad.

Meanwhile, as the pressure formed on the contact surface of the thermal transfer pad 200 increases, the contact thermal resistance may decrease, which is highly important for the performance of the heat transfer pad 200. There are many factors to consider in advance to increase the fastening pressure of the heat transfer pad 200, such as the risk of component failure due to force concentration, the stability of the fastening structure, and the convergence of thermal resistance due to pressure increase, but by improving the contact pressure, pressure drops and thermal insulation that may be caused by thermal deformation can be prevented or reduced in advance.

According to experimental results, the increase in thermal resistance when the pressure decreases from 0.99 MPa to 0.33 MPa is greater than when the pressure decreases from 0.099 MPa to 0.033 MPa. In other words, the higher the pressure, the more likely it is to maintain thermal transfer, even if there are structural changes. The present disclosure provides the heat transfer pad 200 with a corrugated structure necessary for improving thermal transfer capability during uneven contact. The corrugated structure of the heat transfer pad 200 may be a simple, repeating array or a structure designed for relevant components.

Embodiments of the present disclosure have been described above with reference to the accompanying drawings, but the present disclosure is not limited thereto and may be implemented in various different forms. It will be understood that the present disclosure can be implemented in other specific forms without changing the technical concept or gist of the present disclosure. Therefore, it should be understood that the embodiments set forth herein are illustrative in all respects and not limiting.

What is claimed is:

1. A substrate treating apparatus comprising:
a chamber housing;
a substrate support unit configured to support a substrate within the chamber housing;
a showerhead unit configured to provide a process gas into the chamber housing; and
a plasma generation unit configured to generate plasma for treating the substrate within the chamber housing using the process gas,
wherein
the substrate support unit includes a base plate, a dielectric layer, which is disposed on the base plate, and a thermal transfer pad, which is disposed between the base plate and the dielectric layer and bonds the base plate and the dielectric layer together, and
the thermal transfer pad includes a plurality of corrugated patterns.

2. The substrate treating apparatus of claim 1, wherein
the thermal transfer pad includes a film body and a plurality of first protrusion patterns, which are formed on a surface of the film body, and
the first protrusion patterns are formed on an upper or lower surface of the film body.

3. The substrate treating apparatus of claim 1, wherein the thermal transfer pad includes a film body, a plurality of first protrusion patterns, which are formed on an upper surface of the film body, and a plurality of second protrusion patterns, which are formed on a lower surface of the film body.

4. The substrate treating apparatus of claim 3, wherein the first protrusion patterns and the second protrusion patterns are symmetrically formed in a vertical direction.

5. The substrate treating apparatus of claim 3, wherein the first protrusion patterns and the second protrusion patterns are asymmetrically formed in a vertical direction.

6. The substrate treating apparatus of claim 1, wherein the corrugated patterns are formed using first and second rollers.

7. The substrate treating apparatus of claim 6, wherein at least one of the first and second rollers is a rotating body with a plurality of protrusions formed on its surface.

8. The substrate treating apparatus of claim 6, wherein the first and second rollers rotate in opposite directions.

9. The substrate treating apparatus of claim 1, wherein
the thermal transfer pad includes a film body, a coating layer, which is formed on the film body, and a plurality of third protrusion patterns, which are formed on a surface of the coating layer, and
the third protrusion patterns are formed on an upper or lower surface of the coating layer.

10. The substrate treating apparatus of claim 9, wherein
the third protrusion patterns are formed on the upper surface of the coating layer, and
the film body does not include the corrugated patterns.

11. The substrate treating apparatus of claim 9, wherein the thermal transfer pad further includes a plurality of first protrusion patterns, which are formed on a surface of the film body.

12. The substrate treating apparatus of claim 11, wherein
the first protrusion patterns are formed on an upper surface of the film body,
the third protrusion patterns are formed on a lower surface of the coating layer, and
the first protrusion patterns and the third protrusion patterns alternate with one another.

13. The substrate treating apparatus of claim 1, wherein the thermal transfer pad includes a film body, a coating layer, which is formed on the film body, a plurality of first protrusion patterns, which are formed on an upper surface of the film body, a plurality of third protrusion patterns, which are formed on an upper surface of the coating layer, and a plurality of fourth protrusion patterns, which are formed on a lower surface of the coating layer.

14. The substrate treating apparatus of claim 13, wherein the first protrusion patterns and the fourth protrusion patterns alternate with one another.

15. The substrate treating apparatus of claim 13, wherein the fourth protrusion patterns have a greater width than the first protrusion patterns.

16. The substrate treating apparatus of claim 13, wherein the coating layer is formed along a profile of the upper surface of the film body.

17. The substrate treating apparatus of claim 2, wherein the first protrusion patterns are formed to be wider or have a uniform width in a direction from the surface of the film body to the outside.

18. A substrate support unit configured to support a substrate in equipment that treats the substrate using plasma, the substrate support unit comprising:
a base plate;
a dielectric layer disposed on the base plate; and
a thermal transfer pad disposed between the base plate and the dielectric layer and bonding the base plate and the dielectric layer together,
wherein the thermal transfer pad includes a plurality of corrugated patterns.

19. The substrate support unit of claim 18, wherein
the thermal transfer pad includes a film body and a coating layer, which is formed on a surface of the film body, and
the corrugated patterns are formed on at least one of the film body and the coating layer.

20. A substrate treating apparatus comprising:
a chamber housing;
a substrate support unit configured to support a substrate within the chamber housing;
a showerhead unit configured to provide a process gas into the chamber housing; and
a plasma generation unit configured to generate plasma for treating the substrate within the chamber housing using the process gas,
wherein
the substrate support unit includes a base plate, a dielectric layer, which is disposed on the base plate, and a thermal transfer pad, which is disposed between the base plate and the dielectric layer and bonds the base plate and the dielectric layer together,
the thermal transfer pad includes a film body, a plurality of first protrusion patterns, which are formed on an upper surface of the film body, and a plurality of second protrusion patterns, which are formed on a lower surface of the film body, and
the first protrusion patterns and the second protrusion patterns are symmetrically formed in a vertical direction and are formed of the same material.
